(19) United States
(12) Patent Application Publication
(10) Pub. No.: US 2021/0384045 A1
(43) Pub. Date: Dec. 9, 2021

(54) METHOD AND ARRANGEMENT FOR SEMICONDUCTOR MANUFACTURING

(71) Applicant: Nanosized Sweden AB, Uppsala (SE)

(72) Inventors: Harald Näslund, Stockholm (SE); Mats Malmqvist, Uppsala (SE)

(21) Appl. No.: 17/288,169

(22) PCT Filed: Oct. 23, 2019
(86) PCT No.: PCT/SE2019/051042

§ 371 Date: Apr. 23, 2021

(30) Foreign Application Priority Data
Oct. 24, 2018 (SE) 18513119

(51) Int. Cl. H01L 21/67; C02F 1/00; H01L 21/02

(52) U.S. Cl. CPC H01L 21/6704; C02F 2103/04; H01L 21/02052; C02F 1/006

(57) ABSTRACT

A washing water supply arrangement (50) comprises an ultra-pure water production unit (54), a supply pipe (52), an operation control (53) and an ultra-pure water impellent arrangement (55). A first end of the supply pipe (52) is connected to an output from the ultra-pure water production unit (54). A second end of the supply pipe is adapted for being connected to a semiconductor washing apparatus. The operation control (53) is configured for controlling the ultra-pure water production unit (54) to produce a pre-determined amount of ultra-pure water upon demand. The ultra-pure water impellent arrangement (55) has access to a source of an inert gas and is configured for rinsing the supply pipe (52) from water with the inert gas after delivery of the pre-determined amount of ultra-pure water. A semiconductor washing system, a semiconductor production system and a method for supplying washing water are also disclosed.

### TECHNICAL FIELD

The present disclosure relates in general to semiconductor manufacturing and in particular to washing procedures during semiconductor manufacturing.

### BACKGROUND

The quality of semiconductor products is heavily dependent on the cleanliness during production. Production of semiconductor wafers is today typically performed in a production line at least partially contained in a clean area. The importance of clean conditions during manufacturing increases with decreasing line widths of the components of the produced semiconductor products.

In the production of electronic components, the general trend today is to produce electronic circuits with smaller and smaller line-widths. Today, some electronics producers offer commercially available nano-chips with linewidth of around 400 nm. However, in research projects, even smaller linewidths, down to 10 or even 5 nm have been reported. It is thus requested by many users of small electronic circuits to have chips with line widths down to 10 or 5 nm available as commercial products.

However, there is always a considerable step between research results and an available commercial product. The procedures that are used during research development are not always appropriate to directly implement in a large-scale production.

A production line may comprise 50 or even up to 100 or more process steps. Particles that come into contact with the chip during the manufacturing is one of the limiting factors for production of small linewidth electronics. To this end, the entire production line is typically kept within an ultra-clean environment with as little human contact as possible. Between certain process steps, cleaning of the chip is necessary, e.g. for removing excess chemical substances from the preceding process step or particles.

Typically, an ultra-pure water (UPW) production unit produces ultra-pure water and stores it in a tank. In each cleaning step, this UPW is allowed to flush the chip in order to remove chemicals and particles.

In the published U.S. Pat. No. 6,461,519 B1, a process for producing ultra-pure water intended for semiconductor manufacturing is disclosed. In a first treatment step, untreated water, e.g. municipal water or spring water, is pre-treated to reach a certain level of cleanliness. A final treatment step is decentralized, with a respective final purification unit provided in a service area in close proximity to the clean area of each manufacturing unit. This division of the final treatment enables the use of low-cost pipes from the first treatment unit to the respective final treatment units. The short distance between each final treatment unit and the corresponding manufacturing unit utilizes high-quality pipes, contributing less to contamination.

Such approaches bring the cleanliness of the washing water a step forward. However, the remaining low-contaminating supply lines still contributes to contamination, and all storage of ultra-pure water in storages and/or pipes waiting for a next washing step still results in an increased contamination.

### SUMMARY

A general object is to provide methods and devices for improving the cleanliness of ultra-pure water for semiconductor production.

The above object is achieved by methods and devices according to the independent claims. Preferred embodiments are defined in dependent claims.

One advantage with the proposed technology is that the cleanliness of ultra-pure water provided to a washing step of a semiconductor production line is improved. Other advantages will be appreciated when reading the detailed description.

### BRIEF DESCRIPTION OF THE DRAWINGS

The invention, together with further objects and advantages thereof, may best be understood by making reference to the following description taken together with the accompanying drawings, in which:

FIG. 1 schematically illustrates an embodiment of a semiconductor production system;

FIG. 2 illustrates an embodiment of a semiconductor manufacturing stage;

FIG. 3 illustrates a flow diagram of steps of an embodiment of a method for supplying washing water; and

FIG. 4 illustrates a schematic drawing of an embodiment of a washing water supply arrangement.

### DETAILED DESCRIPTION

Throughout the drawings, the same reference numbers are used for similar or corresponding elements.

Ultra-pure water has interesting properties that could be used for cleaning purposes. Due to the lack of dissolved substances, far below the levels of drinking water, ultra-pure water has a strong affinity for almost any substances. The use of ultra-pure water as cleaning liquid in a semiconductor manufacturing line is therefore highly advantageous and known, as such, since many years. The absence of particles also becomes of importance when nano-chips are to be produced, since the remains of particles from the cleaning liquid may disturb the geometrical structures obtained in the manufacturing process.

Due to the high affinity for contamination, ultra-pure water will also dissolve substances during storage and transportation. Large efforts have been made in order to minimize storage times and transport distances between the ultra-pure water production unit and the washing steps in the semiconductor manufacturing line. Pipes and storage vessels covered with material that to some degree withstands the action of the ultra-pure water are used. However, such materials are expensive and do not completely avoid the contamination. When going to linewidths of the produced chips of a few nanometres, the quality of the water used for washing between the different production steps becomes even more challenging.

The dissolution of substances into ultra-pure water does not only depend on the material surrounding it, but will also depend on the contact time, i.e. how long time the ultra-pure water can act to dissolve the substances. Therefore, all types of storages are disadvantageous. Furthermore, long transport pipes also increase the exposure time for the ultra-clean water.

The herein presented technology therefore aims for reducing the time that the ultra-pure water is in contact with other parts than the objects to be cleaned.

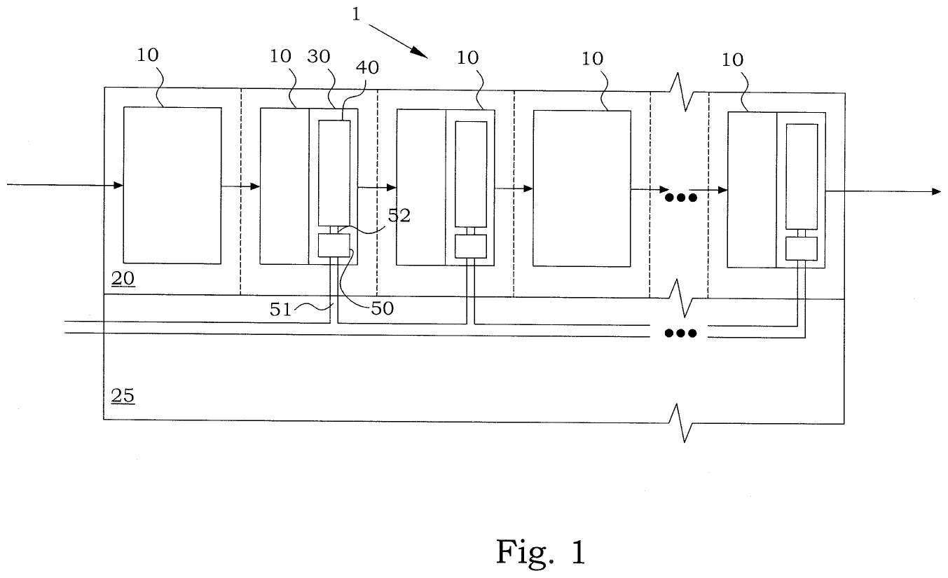

FIG. 1 illustrates schematically an embodiment of a semiconductor production system 1 having a line of semiconductor manufacturing stages 10 contained in a clean-room area 20. The line comprises at least one semiconductor manufacturing stage 10, but typically a multitude, e.g. 50-100 stages. A service area 25 is located along and in connection with the clean-room area in order to supply necessary services that cannot or at least are unnecessary to be placed in the clean-room area 20.

At least one of the semiconductor manufacturing stages 10, and typically a multitude, comprises a semiconductor washing system 30 having a semiconductor washing apparatus 40 and a washing water supply arrangement 50. The washing apparatus 40 rinses the semiconductor items by dipping, agitating or centrifuging or a combination thereof and is operated manually or automatically. The washing water supply arrangement 50 is supplied with water from the service area 25 by a water pipe 51. The water supplied by the water pipe 51 is clean, but not ultra-pure, typically normal tap water.

In prior art systems, the production of ultra-pure water is typically instead provided in the service area and the ultra-pure water is subsequently transported into the clean-room area by supply pipes.

By locating the washing water supply arrangement 50 in the clean-room area 20, a supply pipe 52, connecting the washing water supply arrangement 50 to the semiconductor washing apparatus 40 can be made extremely short. The present development of washing water supply arrangements allows for clean-room operation. When producing ultra-pure water, a certain amount of heat is dissipated into the volume around the production unit. For large production units, such as is used today in the service area, the amount of emitted heat would cause problems if the large production units are moved into the clean-room area. However, for small local ultra-pure water production units spread along the entire production line, the heat emission would typically be acceptable even without particular cooling arrangements.

The semiconductor production system 1 comprises of course many other functionalities, both in the clean-room area 20 and in the service area 25. However, such functionalities are, as such, well-known in prior art and are not of any crucial importance for the technology presented herein and is therefore omitted in the present description.

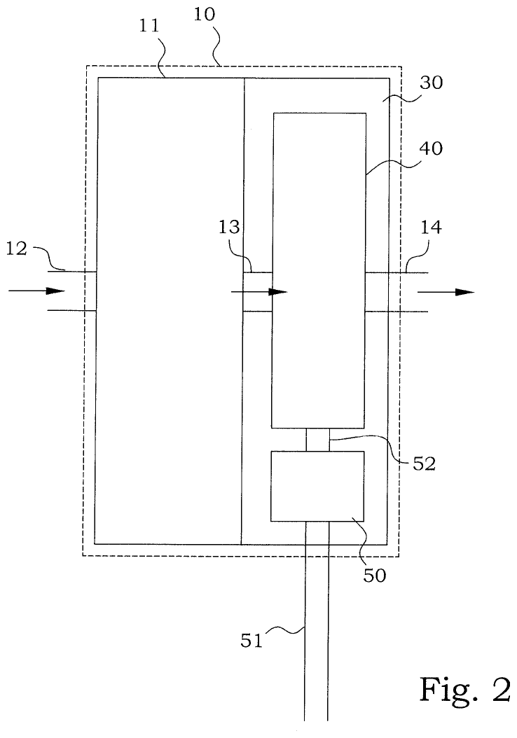

FIG. 2 illustrates an embodiment of a semiconductor manufacturing stage 10 in more detail. The semiconductor manufacturing stage 10 comprises a process unit 11 equipped for performing a process step of the semiconductor manufacturing process. Semiconductor items are entered into the process unit 11 through an inlet 12, either as raw material or from a preceding stage. The semiconductor items are processed in the process unit 11 according to processes, as such known in prior art. When the process is finished and the processed semiconductor items are to be washed, the semiconductor items are transferred in to the semiconductor washing apparatus 40 of the semiconductor washing system 30 through a connection 13.

Alternatively, the process unit 11 and the semiconductor washing apparatus 40 could be integrated into one common unit.

The washing process in the semiconductor washing apparatus 40 requires a certain amount of ultra-pure water. This amount is typically determined in connection with the installation of the line e.g. by monitoring a discarding rate as a function of ultra-pure water amount. Such a determined required amount of ultra-pure water may also be updated at different occasions later during the manufacturing processes.

When the processed semiconductor items are ready to be washed, the washing water supply arrangement 50 is demanded to supply ultra-pure water to the semiconductor washing apparatus 40 in a pre-determined amount corresponding to the needs of the semiconductor washing apparatus 40. The operation of this supply will be discussed more in detail further below.

When the washing process is finished, the washed semiconductor items are outputted through an output 14 to a following semiconductor manufacturing stage 10 or as a final product.

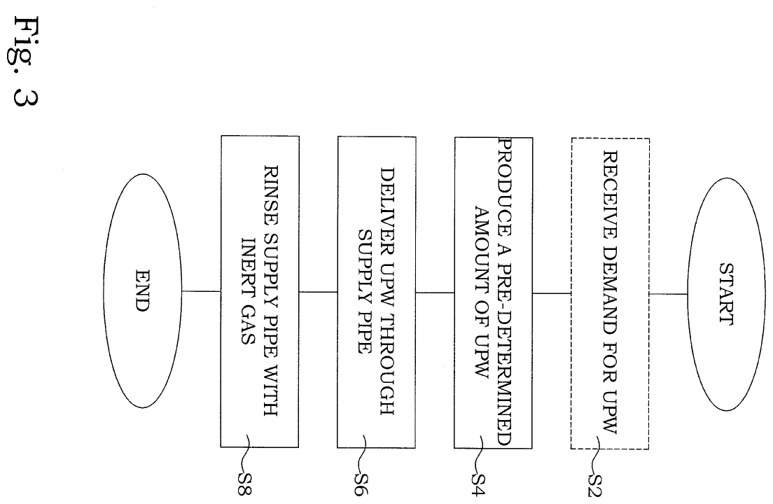

FIG. 3 illustrates a flow diagram of steps of an embodiment of a method for supplying washing water. In step S2, a demand for supply of a pre-determined amount of ultra-pure water is received by a washing water supply arrangement. In step S4, the pre-determined amount of ultra-pure water is produced. This production is thus made on demand only. In Step S6, the pre-determined amount of ultra-pure water is delivered, in direct connection with the production, to a semiconductor washing apparatus through a supply pipe. When the delivery is made, there is typically some remaining ultra-pure water in the supply pipe. If such ultra-pure water is allowed to stay in the supply pipe during the interval to the next delivery occasion, the ultra-pure water may be considerably contaminated. Therefore, in step S8, the supply pipe is rinsed from water. This rinsing is performed with an inert gas after, preferably immediately after, the delivery of the pre-determined amount of ultra-pure water through the supply pipe. In such a way, there is no remaining ultra-pure water within the supply system.

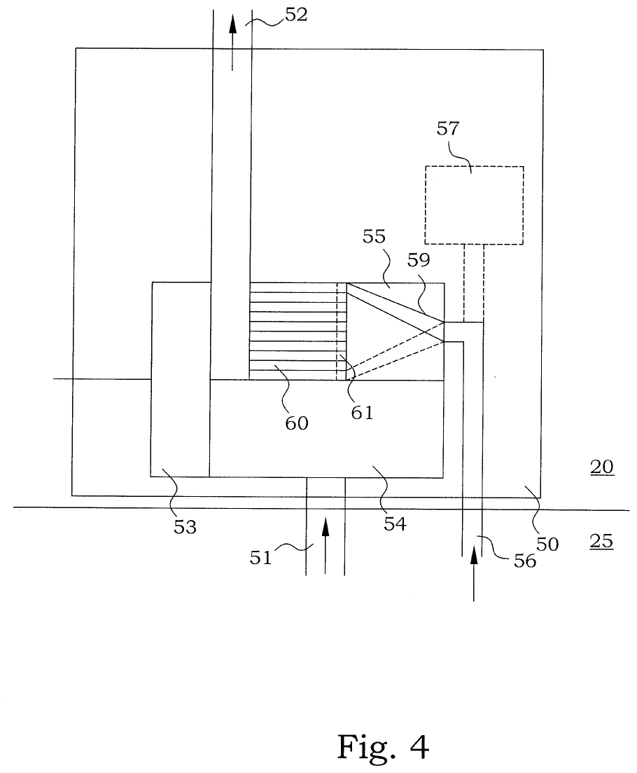

FIG. 4 illustrates a schematic drawing of an embodiment of a washing water supply arrangement 50. The water pipe 51 connects to an ultra-pure water production unit 54. An ultra-pure water impellent arrangement 55 is arranged for delivering ultra-pure water from the ultra-pure water production unit 54 out through the supply pipe 52. The supply pipe 52 is connected by a first end to the ultra-pure water impellent arrangement 55 and by a second end to a semiconductor washing apparatus. The ultra-pure water impellent arrangement 55 has access to a source of an inert gas, indicated by a gas pipe 56 connected to a source located e.g. in the service area. Alternatively, a gas container 57 can be provided.

In one embodiment, the ultra-pure water production unit 54 produces ultra-pure water on demand, as will be described more in detail below. The ultra-pure water is provided into a plurality of receptacles 60. Preferably, the receptacles 60 are filled in a sequential manner, thereby facilitating a phase-shifted emptying procedure, as will be described more in detail below. When the ultra-pure water of a receptacle 60 is to be emptied into the supply pipe 52, a gas connection 59 is connected between the gas pipe 56, containing pressurized inert gas, and a first end of the receptacle 60 to be emptied. The pressurized inert gas thereby blows the content of the receptacle 60 through a second end into the supply pipe 52 for further transport into the washing apparatus. Inert gas with a typical pressure of 30 psi are typically already provided in most clean-room facilities and could be advantage be used also for such purposes. The ultra-pure water impellent arrangement 55 is arranged for being able to empty one receptacle 60 at a time during a water supply phase. This can be arranged for either by a movable gas connection 59 as indicated in the figure, or by stationary gas connections with separately operated valves.

In other words, the ultra-pure water production unit 54 comprises a plurality of receptacles 60 into which produced ultra-pure water is entered and out of which the produced ultra-pure water is provided to the supply pipe 52.

In other embodiments, one single receptacle may be used for receiving the freshly produced ultra-pure water to be provided to the supply pipe.

Also, in other embodiments, the delivery of the ultra-pure water through the supply pipe may impelled by other means, e.g. by pumping.

The ultra-pure water impellent arrangement 55 is configured for rinsing the supply pipe 52 from water with the inert gas after delivery of the pre-determined amount of ultra-pure water through said supply pipe 52. When additional volumes or pipes are used for contacting the ultra-pure water, such as e.g. the receptacles 60 of FIG. 4, also these are preferably rinsed after use. The inert gas is used for this purpose, for blowing away remaining ultra-pure water from the supply pipe 52 and at least partly drying the inner surfaces of the supply pipe 52. This ensures that there is no water spending any longer times in the supply pipe 52 (or receptacle, if any), which in turn ensures that there is no contamination particles or contamination material dissolved from the inner surface of the supply pipe 52.

The washing water supply arrangement 50 further comprises an operation control 53, controlling the operation of the ultra-pure water production unit 54. The operation control 53 is configured for receiving a demand for ultra-pure water. The amount of ultra-pure water to be produced is either pre-configured or is attached to the demand. Thus, the operation control 53 is preferably configured for allowing setting of the pre-determined amount of ultra-pure water. The operation control 53 is configured for, as a response to the demand, controlling the ultra-pure water production unit to produce the pre-determined amount of ultra-pure water.

Preferably, the demand for ultra-pure water is also accompanied by a delivery time, at which the ultra-pure water is to be provided. The operation control 53 preferably determines a production start time, which is suitable for ensuring that the requested amount of ultra-pure water, freshly produced, is made available at the demanded time. This production time should be planned to ensure that there is ultra-pure water available when the washing is to be started, so that there are no stays in the production line. However, at the same time the production time should be planned to ensure that the mean time between production and consumption is kept as low as possible, i.e. that the last produced drops of ultra-pure water are produced just before they are provided into the supply pipe 52.

In other words, the operation control 53 is configured for controlling a timing of an operation of the production unit 54 of ultra-pure water for providing the pre-determined amount of ultra-pure water, freshly produced, at a time set by a received demand.

In the embodiment of FIG. 4, the receptacles 60 can be filled sequentially, and when the semiconductor washing apparatus is ready to receive the ultra-pure water, the receptacles 60 are emptied in the same order. This gives even a possibility to optimize the timing in that the last (few) receptacles 60 still can be filled at the same time as the first ones are being emptied. The storage time within the receptacles is thus reduced.

Preferably, the pre-determined amount of ultra-pure water is equal to an amount of water required by a washing operation in the semiconductor washing apparatus, as discussed above.

In a preferred embodiment, the washing water supply arrangement 50 further comprises a water analysis section. Such a section is arranged for measuring a particle content in an ultra-pure water test volume extracted from the pre-determined amount of ultra-pure water. The water of the ultra-pure water test volume is not allowed to be re-entered in to the washing procedure after the analysis, which means that the pre-determined amount of ultra-pure water has to compensate for this deviated volume as well. A verification of the cleanliness of the ultra-pure water can thus be achieved. If the amount of defect semiconductor products becomes too large, a back-reference to the actually used water quality is available, which may assist in finding malfunctioning parts in the production line. Such an analysis can, at least for particle sizes above and slightly below 100 nm, be performed according to standard analysis means, known as such in prior art, e.g. based on precision resistivity measurements.

The embodiments described above are to be understood as a few illustrative examples of the present invention. It will be understood by those skilled in the art that various modifications, combinations and changes may be made to the embodiments without departing from the scope of the present invention. In particular, different part solutions in the different embodiments can be combined in other configurations, where technically possible. The scope of the present invention is, however, defined by the appended claims.

1. A washing water supply arrangement, comprising:
an ultra-pure water production unit;
a supply pipe, a first end of which being connected to an output from said ultra-pure water production unit;
wherein a second end of said supply pipe being adapted for being connected to a semiconductor washing apparatus;
an operation control for said ultra-pure water production unit;
wherein said operation control being configured for controlling said ultra-pure water production unit to produce a pre-determined amount of ultra-pure water upon demand; and
an ultra-pure water impellent arrangement having access to a source of an inert gas;
wherein ultra-pure water impellent arrangement being configured for rinsing said supply pipe from water with said inert gas after delivery of said pre-determined amount of ultra-pure water through said supply pipe.

2. The washing water supply arrangement according to claim 1, wherein said ultra-pure water impellent arrangement being configured for driving said pre-determined amount of ultra-pure water through said supply pipe impelled by said inert gas.

3. The washing water supply arrangement according to claim 1, wherein said ultra-pure water production unit is configured for being operable in a clean-room area.

4. The washing water supply arrangement according to claim 1, wherein said operation control being configured for allowing setting of said pre-determined amount of ultra-pure water.

5. The washing water supply arrangement according to claim 1, wherein said operation control being configured for controlling a timing of an operation of said production unit of ultra-pure water for providing said pre-determined amount of ultra-pure water, freshly produced, at a time set by a received demand.

6. The washing water supply arrangement according to claim 1, wherein said ultra-pure water production unit comprises a plurality of receptacles into which produced ultra-pure water is entered and out of which said produced ultra-pure water is provided to said supply pipe.

7. The washing water supply arrangement according to claim 1, further comprising a water analysis section, arranged for measuring a particle content in an ultra-pure water test volume extracted from said pre-determined amount of ultra-pure water.

8. A semiconductor washing system, comprising
a washing water supply arrangement according to claim 1; and
a semiconductor washing apparatus, to which said second end of said supply pipe being connected.

9. The semiconductor washing system according to claim 8, wherein said pre-determined amount of ultra-pure water is equal to an amount of water required by a washing operation in said semiconductor washing apparatus.

10. A semiconductor production system, comprising:
a clean-room area containing at least one semiconductor manufacturing stage; and
a service area located in connection with said clean-room area;
wherein at least one of said at least one semiconductor manufacturing stage comprises a semiconductor washing system according to claim 8, located within said clean-room area;
wherein said washing water supply arrangement of said semiconductor washing system being supplied with water from said service area.

11. A method for supplying washing water, comprising the steps of:
producing a pre-determined amount of ultra-pure water upon demand; and
delivering, in connection with said production, said pre-determined amount of ultra-pure water to a semiconductor washing apparatus through a supply pipe; and
rinsing said supply pipe from water with an inert gas after said delivery of said pre-determined amount of ultra-pure water through said supply pipe.

12. The method according to claim 11, wherein said delivering of said ultra-pure water through said supply pipe comprises impelling said ultra-pure water through said supply pipe by said inert gas.

13. The method according to claim 11, comprising the further step of measuring a particle content in an ultra-pure water test volume extracted from said pre-determined amount of ultra-pure water.

14. The semiconductor production system according to claim 10, wherein said pre-determined amount of ultra-pure water is equal to an amount of water required by a washing operation in said semiconductor washing apparatus.

15. The washing water supply arrangement according to claim 2, wherein said ultra-pure water production unit is configured for being operable in a clean-room area.

16. The washing water supply arrangement according to claim 2, wherein said operation control being configured for allowing setting of said pre-determined amount of ultra-pure water.

17. The washing water supply arrangement according to claim 3, wherein said operation control being configured for allowing setting of said pre-determined amount of ultra-pure water.

18. The washing water supply arrangement according to claim 15, wherein said operation control being configured for allowing setting of said pre-determined amount of ultra-pure water.

19. The washing water supply arrangement according to claim 2, wherein said operation control being configured for controlling a timing of an operation of said production unit of ultra-pure water for providing said pre-determined amount of ultra-pure water, freshly produced, at a time set by a received demand.

20. The washing water supply arrangement according to claim 3, wherein said operation control being configured for controlling a timing of an operation of said production unit of ultra-pure water for providing said pre-determined amount of ultra-pure water, freshly produced, at a time set by a received demand.
